(19) United States
(12) Patent Application Publication
(10) Pub. No.: US 2016/0233226 A1
(43) Pub. Date: Aug. 11, 2016

(54) SEMICONDUCTOR MEMORY DEVICE AND METHOD OF MANUFACTURING THE SAME

(71) Applicant: Kabushiki Kaisha Toshiba, Minato-ku (JP)

(72) Inventor: Takeshi MURATA, Yokkaichi (JP)

(73) Assignee: Kabushiki Kaisha Toshiba, Minato-ku (JP)

(21) Appl. No.: 14/799,779

(22) Filed: Jul. 15, 2015

Related U.S. Application Data
(60) Provisional application No. 62/112,987, filed on Feb. 6, 2015.

(51) Int. Cl. H01L 27/115; H01L 21/283; H01L 21/28

(52) U.S. Cl. CPC H01L 27/11524; H01L 21/28273; H01L 21/283

(57) ABSTRACT

A method of manufacturing a semiconductor memory device according to an embodiment comprises: stacking a first insulating layer on a semiconductor layer, the first insulating layer being provided with a first region, a second region, and a third region that are adjacent in a first direction; stacking a charge accumulation layer formation layer; stacking a second insulating layer; and stacking a first conductive layer. The method comprises: in the second region on the semiconductor layer, removing the first insulating layer, the charge accumulation layer formation layer, the second insulating layer, and the first conductive layer to expose the semiconductor layer. Moreover, the method comprises: stacking in the second region a third insulating layer; and stacking a second conductive layer. Furthermore, the method comprises: exposing an upper surface of the semiconductor layer in the third region.

### CROSS-REFERENCE TO RELATED APPLICATIONS

This application is based upon and claims the benefit of U.S. Provisional Patent Application No. 62/112,987, filed on Feb. 6, 2015, the entire contents of which are incorporated herein by reference.

### FIELD

Embodiments described herein relate to a semiconductor memory device and a method of manufacturing the same.

### BACKGROUND

### Description of the Related Art

A memory cell configuring a nonvolatile semiconductor memory device such as a NAND type flash memory includes a semiconductor layer, a control gate, and a charge accumulation layer. The memory cell changes its threshold voltage according to a charge accumulated in the charge accumulation layer and stores a magnitude of this threshold voltage as data. In recent years, enlargement of capacity and raising of integration level has been proceeding in such a nonvolatile semiconductor memory device.

### BRIEF DESCRIPTION OF THE DRAWINGS

FIG. 1 is a block diagram of a nonvolatile semiconductor memory device according to a first embodiment.

FIG. 2 is a circuit diagram showing a configuration of part of the same nonvolatile semiconductor memory device.

FIG. 3 is a schematic cross-sectional view showing a configuration of part of the same nonvolatile semiconductor memory device.

FIG. 4 is a schematic plan view showing a configuration of part of the same nonvolatile semiconductor memory device.

FIG. 5 is a schematic plan view showing a configuration of part of the same nonvolatile semiconductor memory device.

FIG. 6 is a cross-sectional view showing a manufacturing process of the same nonvolatile semiconductor memory device.

FIG. 7 is a cross-sectional view showing a manufacturing process of the same nonvolatile semiconductor memory device.

FIG. 8 is a cross-sectional view showing a manufacturing process of the same nonvolatile semiconductor memory device.

FIG. 9 is a cross-sectional view showing a manufacturing process of the same nonvolatile semiconductor memory device.

FIG. 10 is a cross-sectional view showing a manufacturing process of the same nonvolatile semiconductor memory device.

FIG. 11 is a cross-sectional view showing a manufacturing process of the same nonvolatile semiconductor memory device.

FIG. 12 is a cross-sectional view showing a manufacturing process of the same nonvolatile semiconductor memory device.

FIG. 13 is a cross-sectional view showing a manufacturing process of the same nonvolatile semiconductor memory device.

FIG. 14 is a cross-sectional view showing a manufacturing process of the same nonvolatile semiconductor memory device.

FIG. 15 is a cross-sectional view showing a manufacturing process of the same nonvolatile semiconductor memory device.

FIG. 16 is a cross-sectional view showing a manufacturing process of a nonvolatile semiconductor memory device according to a second embodiment.

FIG. 17 is a cross-sectional view showing a manufacturing process of the same nonvolatile semiconductor memory device.

FIG. 18 is a cross-sectional view showing a manufacturing process of the same nonvolatile semiconductor memory device.

FIG. 19 is a cross-sectional view showing a manufacturing process of the same nonvolatile semiconductor memory device.

FIG. 20 is a cross-sectional view showing a manufacturing process of the same nonvolatile semiconductor memory device.

FIG. 21 is a cross-sectional view showing a manufacturing process of the same nonvolatile semiconductor memory device.

FIG. 22 is a schematic cross-sectional view showing a configuration of part of a nonvolatile semiconductor memory device according to a third embodiment.

FIG. 23 is a cross-sectional view showing a manufacturing process of the same nonvolatile semiconductor memory device.

FIG. 24 is a cross-sectional view showing a manufacturing process of the same nonvolatile semiconductor memory device.

FIG. 25 is a cross-sectional view showing a manufacturing process of the same nonvolatile semiconductor memory device.

FIG. 26 is a cross-sectional view showing a manufacturing process of the same nonvolatile semiconductor memory device.

FIG. 27 is a cross-sectional view showing a manufacturing process of the same nonvolatile semiconductor memory device.

FIG. 28 is a cross-sectional view showing a manufacturing process of the same nonvolatile semiconductor memory device.

FIG. 29 is a cross-sectional view showing a manufacturing process of the same nonvolatile semiconductor memory device.

FIG. 30 is a cross-sectional view showing a manufacturing process of the same nonvolatile semiconductor memory device.

FIG. 31 is a cross-sectional view showing a manufacturing process of the same nonvolatile semiconductor memory device.

### DETAILED DESCRIPTION

A method of manufacturing a semiconductor memory device described below manufactures a semiconductor memory device comprising: a NAND string provided in a first region on a semiconductor layer extending in a first direction, the NAND string including a plurality of memory cells connected in series; and a select gate transistor connected to an end of the NAND string in a second region on the semiconductor layer, the second region being adjacent to the first region from the first direction. This method comprises: stacking on the semiconductor layer a first insulating layer which will be a gate insulating layer of the memory cell; stacking on this first insulating layer a charge accumulation layer formation layer which will be a charge accumulation layer of the memory cell; stacking on this charge accumulation layer formation layer a second insulating layer which will be an inter-gate insulating layer of the memory cell; and stacking on this second insulating layer a first conductive layer which will be a control gate electrode of the memory cell. In addition, this method comprises: in the second region, removing the first insulating layer, the charge accumulation layer formation layer, the second insulating layer, and the first conductive layer to expose the semiconductor layer. Moreover, this method comprises: stacking in the second region a third insulating layer which will be a gate insulating layer of the select gate transistor; and forming on the third insulating layer a second conductive layer which will be a gate electrode of the select gate transistor.

Embodiments of a semiconductor memory device and a method of manufacturing the same will be described below with reference to the drawings.

### First Embodiment

### Overall Configuration

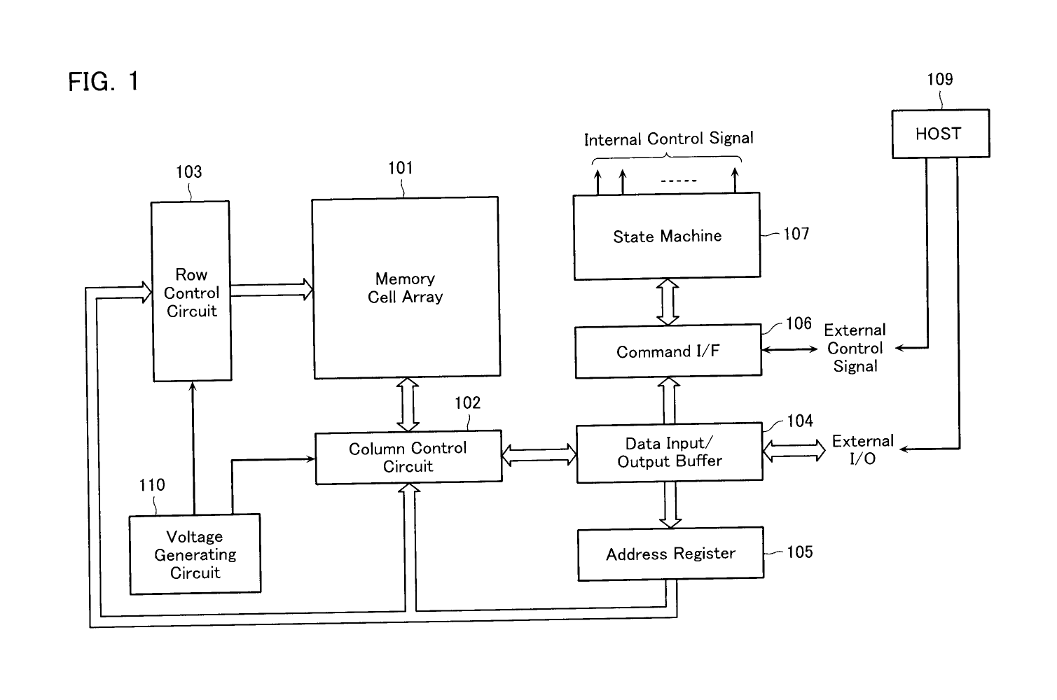

FIG. 1 is a block diagram of a nonvolatile semiconductor memory device according to a first embodiment. This nonvolatile semiconductor memory device includes a memory cell array 101 having a plurality of memory cells MC disposed substantially in a matrix therein, and comprising a bit line BL and a word line WL disposed orthogonally to each other and connected to these memory cells MC. Provided in a periphery of this memory cell array 101 are a column control circuit 102 and a row control circuit 103. The column control circuit 102 controls the bit line BL and performs data erase of the memory cell, data write to the memory cell, and data read from the memory cell. The row control circuit 103 selects the word line WL and applies a voltage for data erase of the memory cell, data write to the memory cell, and data read from the memory cell.

A data input/output buffer 104 is connected to an external host 109, via an I/O line, and receives write data, receives an erase command, outputs read data, and receives address data or command data. The data input/output buffer 104 sends received write data to the column control circuit 102, and receives data read from the column control circuit 102 to be outputted to external. An address supplied to the data input/output buffer 104 from external is sent to the column control circuit 102 and the row control circuit 103 via an address register 105.

Moreover, a command supplied to the data input/output buffer 104 from the host 109 is sent to a command interface 106. The command interface 106 receives an external control signal from the host 109, determines whether data inputted to the data input/output buffer 104 is write data or a command or an address, and, if a command, receives the data and transfers the data to a state machine 107 as a command signal.

The state machine 107 performs management of this nonvolatile semiconductor memory device overall, receives a command from the host 109, via the command interface 106, and performs management of read, write, erase, input/output of data, and so on.

In addition, it is also possible for the external host 109 to receive status information managed by the state machine 107 and judge an operation result. Moreover, this status information is utilized also in control of write and erase.

Furthermore, the state machine 107 controls a voltage generating circuit 110. This control enables the voltage generating circuit 110 to output a pulse of any voltage and any timing.

Now, the pulse formed by the voltage generating circuit 110 can be transferred to any line selected by the column control circuit 102 and the row control circuit 103. These column control circuit 102, row control circuit 103, state machine 107, voltage generating circuit 110, and so on, configure a control circuit in the present embodiment.

[Memory Cell Array 101]

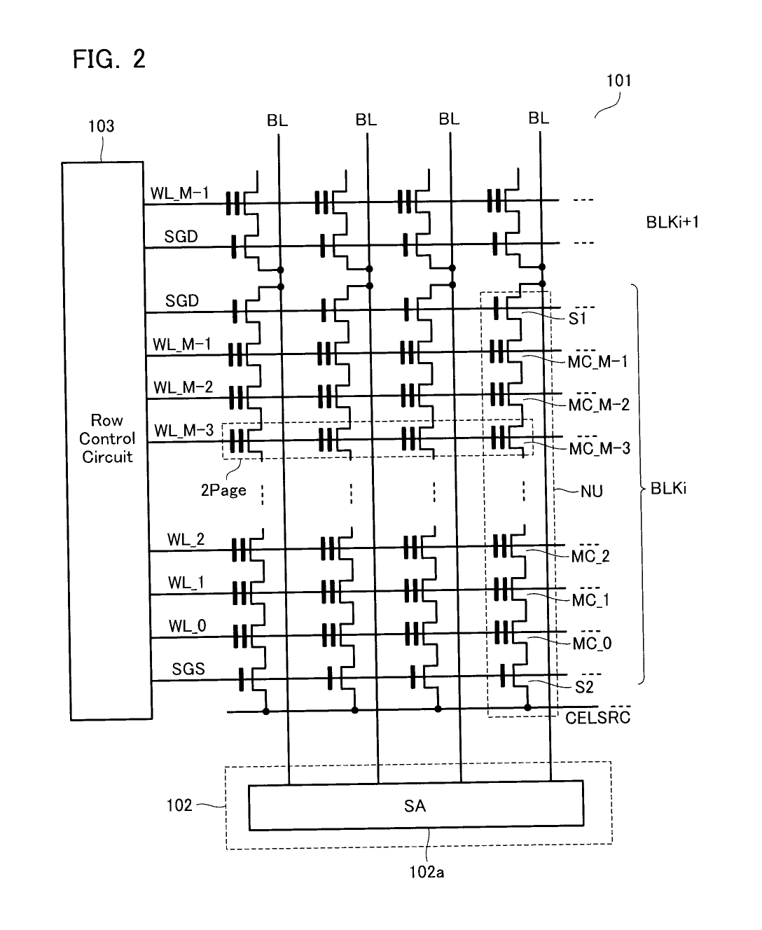

FIG. 2 is a circuit diagram showing a configuration of the memory cell array 101. As shown in FIG. 2, the memory cell array 101 is configured having NAND cell units NU arranged therein, each of the NAND cell units NU comprising select gate transistors S1 and S2 respectively connected to both ends of a NAND string, the NAND string having M electrically rewritable nonvolatile memory cells MC_0 to MC_M−1 connected in series therein, sharing a source and a drain.

The NAND cell unit NU has one end (a select gate transistor S1 side) connected to the bit line BL and the other end (a select gate transistor S2 side) connected to a common source line CELSRC. Gate electrodes of the select gate transistors S1 and S2 are connected to select gate lines SGD and SGS. In addition, control gate electrodes of the memory cells MC_0 to MC_M−1 are respectively connected to word lines WL_0 to WL_M−1. The bit line BL is connected to a sense amplifier 102a of the column control circuit 102, and the word lines WL_0 to WL_M−1 and select gate lines SGD and SGS are connected to the row control circuit 103.

In the case of 2 bits/cell where 2 bits of data are stored in one memory cell MC, data stored in the plurality of memory cells MC connected to one word line WL configures 2 pages (an upper page UPPER and a lower page LOWER) of data.

One block BLK is formed by the plurality of NAND cell units NU sharing the word line WL. One block BLK forms a single unit of a data erase operation. The number of word lines WL in one block BLK in one memory cell array 101 is M, and, in the case of 2 bits/cell, the number of pages in one block is M×2 pages.

[Stacked Structure]

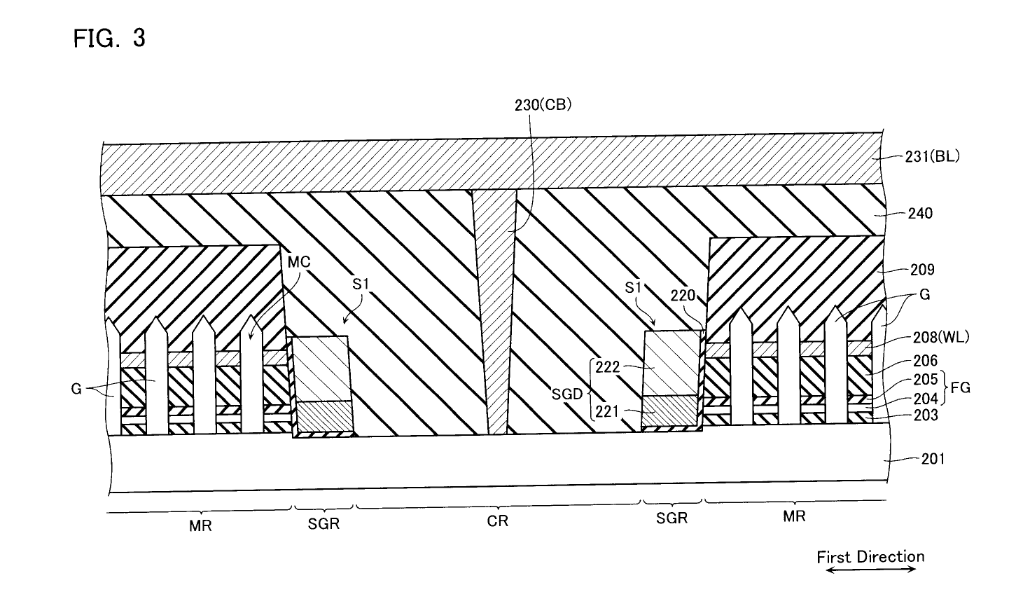

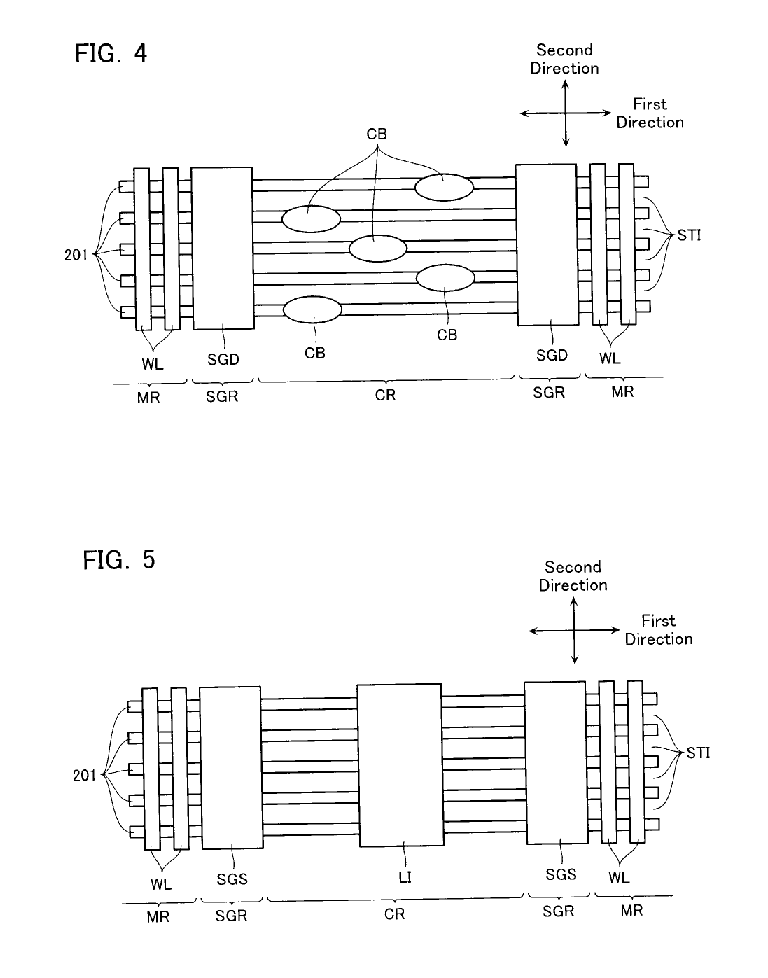

FIG. 3 is a schematic cross-sectional view showing a stacked structure of part of the nonvolatile semiconductor memory device according to the first embodiment. FIGS. 4 and 5 are each a schematic plan view showing a configuration of part of the same nonvolatile semiconductor memory device.

As shown in FIG. 3, in the present embodiment, a memory region MR and a select gate region SGR are provided on a semiconductor layer 201. The memory region MR has a plurality of the memory cells MC formed therein. The select gate region SGR has the select gate transistor S1 or S2 formed therein. In addition, in the present embodiment, a contact region CR is provided on the semiconductor layer 201. The contact region CR has a bit line contact CB or a source line contact LI formed therein. The bit line contact CB connects the semiconductor layer 201 and the bit line BL. The source line contact LI connects the semiconductor layer 201 and the source line CELSRC (FIG. 2). As shown in FIG. 3, the memory region MR, the select gate region SGR, and the contact region CR are aligned in this order in a first direction. Moreover, FIG. 3 exemplifies a connecting portion of the NAND cell unit NU and the bit line BL, but a connecting portion of the NAND cell unit NU and the source line CELSRC (FIG. 2) is also configured substantially similarly.

As shown in FIG. 3, the memory region MR is provided with a plurality of the memory cells MC forming the above-mentioned NAND string. An air gap G insulates between fellow memory cells MC. Moreover, an upper portion of the plurality of memory cells MC is covered by an insulating layer 209, and an upper portion of the insulating layer 209 is further covered by an insulating layer 240.

As shown in FIG. 3, the memory cell MC comprises the following, stacked sequentially therein, namely: the semiconductor layer 201; a first insulating layer 203 that functions as a tunnel insulating layer; a first charge accumulation layer 204 and a second charge accumulation layer 205 that function as a charge accumulation layer FG; a second insulating layer 206 that functions as an inter-gate insulating layer; and a conductive layer 208 that functions as the word line WL (control gate, first conductive layer). As shown in FIGS. 4 and 5, a plurality of the semiconductor layers 201 are arranged, via an STI, in a second direction intersecting the first direction, and the word line WL extends in the second direction so as to intersect these plurality of semiconductor layers 201. Note that film thicknesses of each of the layers may be appropriately adjusted, but a film thickness of the first charge accumulation layer 204 is, for example, 20 nm or less.

The first insulating layer 203 is configured from, for example, silicon oxide (SiO₂). In addition, the first charge accumulation layer 204 is configured from, for example, n type polysilicon. The second charge accumulation layer 205 is configured from, for example, silicon nitride (SiN). Moreover, a metal layer may be formed on an upper surface of the second charge accumulation layer 205. The second insulating layer 206 may be formed from, for example, silicon oxide (SiO₂), but may also adopt a variety of configurations such as a stacked structure configured from hafnium oxide (HfOₓ), silicon oxide (SiO₂), and hafnium oxide (HfOₓ). Moreover, an upper surface of the second insulating layer 206 may be provided with a barrier film such as a stacked film of tantalum nitride (TaN) and tungsten nitride (WN). In addition, the conductive layer 208 is configured from, for example, tungsten (W). The insulating layer 209 is configured from, for example, silane (SiH₄), or the like. Furthermore, the insulating layer 240 is configured from, for example, polysilazane, or the like. Note that materials of each of the layers may be changed appropriately. Moreover, configurations of the tunnel insulating layer, the charge accumulation layer FG, the inter-gate insulating layer, and the word line WL may be changed appropriately.

As shown in FIG. 3, the select gate transistor S1 is formed in the select gate region SGR. The select gate transistor S1 is connected to the NAND string, and, together with the NAND string, configures the NAND cell unit NU. An upper surface and a side surface of the select gate transistor S1 is covered by the insulating layer 240. Note that, although not illustrated in FIG. 3, the select gate transistor S2 is configured substantially similarly to the select gate transistor S1.

As shown in FIG. 3, the select gate transistor S1 comprises the following, stacked sequentially therein, namely: the semiconductor layer 201; a third insulating layer 220 that functions as a gate insulating layer; and the select gate line SGD (second conductive layer). As shown in FIG. 4, the select gate line SGD extends in the second direction so as to intersect the plurality of semiconductor layers 201 arranged in the second direction. Note that as shown in FIG. 5, the select gate line SGS also extends in the second direction so as to intersect the plurality of semiconductor layers 201 arranged in the second direction.

As shown in FIG. 3, the third insulating layer 220 has an L-shaped shape that includes: a lower surface portion covering an upper surface of the semiconductor layer 201; and a side surface portion covering sidewalls of the charge accumulation layer FG, the inter-gate insulating layer 206, and the word line WL positioned at an end of the memory region MR. Moreover, in the present embodiment, the sidewalls of the charge accumulation layer FG, the inter-gate insulating layer 206, and the word line WL positioned at the end of the memory region MR are inclined so as to be closer to the select gate region SGR the closer they are to the semiconductor layer 201 and so as to be more distant from the select gate region SGR the more distant they are from the semiconductor layer 201. Therefore, the side surface portion of the third insulating layer 220 is also inclined so as to be more distant from the memory region MR the closer it is to the semiconductor layer 201 and so as to be closer to the memory region MR the more distant it is from the semiconductor layer 201, along the sidewalls of these layers.

Moreover, as shown in FIG. 3, the select gate line SGD faces the upper surface of the semiconductor layer 201 via the lower surface portion of the third insulating layer 220, and faces the sidewalls of the charge accumulation layer FG, the inter-gate insulating layer 206, and the word line WL positioned at the end of the memory region MR, via the side surface portion of the third insulating layer 220. Furthermore, both end surfaces in the first direction of the select gate line SGD are inclined so as to be more distant from the memory region MR the closer they are to the semiconductor layer 201 and so as to be closer to the memory region MR the more distant they are from the semiconductor layer 201. Furthermore, the upper surface of the select gate line SGD and the side surface on a contact region CR side of the select gate line SGD contact the insulating layer 240.

As shown in FIG. 3, the select gate line SGD may have, for example, a lower portion thereof which is a layer 221 configured from n type polysilicon and an upper portion thereof which is a low-resistance layer 222 configured by siliciding polysilicon. However, the select gate line SGD may be, for example, entirely silicided polysilicon, or may be, for example, a metal.

As shown in FIG. 3, the bit line contact CB is formed in the contact region CR. The bit line contact CB connects the semiconductor layer 201 and the bit line BL. The bit line contact CB is configured from a columnar conductive layer (third conductive layer) 230 that contacts the semiconductor layer 201 at its lower end and contacts the bit line BL at its upper end. As shown in FIG. 4, the bit line contact CB is provided for each of the semiconductor layers 201 arranged in the second direction. Moreover, the bit line contacts CB connected to closely positioned fellow semiconductor layers 201 have different positions in the first direction.

Note that FIG. 3 exemplifies the connecting portion of the NAND cell unit NU and the bit line BL, but the connecting portion of the NAND cell unit NU and the source line CELSRC is also configured substantially similarly. However, as shown in FIG. 5, formed in the connecting portion of the NAND cell unit NU and the source line CELSRC is the source line contact LI that connects the semiconductor layer 201 and the source line CELSRC. The source line contact LI is configured from a plate-like conductive layer (third conductive layer) that contacts the semiconductor layer 201 at its lower end and contacts the source line CELSRC (FIG. 2) at its upper end. As shown in FIG. 5, the source line contact LI is commonly provided for the plurality of semiconductor layers 201 arranged in the second direction.

As described above, in the present embodiment, both side surfaces of the select gate lines SGD and SGS are inclined so as to be more distant from the memory region MR the closer they are to the semiconductor layer 201 and so as to be closer to the memory region MR the more distant they are from the semiconductor layer 201. As will be mentioned later, such a semiconductor memory device can be manufactured comparatively easily, even when the film thickness of the charge accumulation layer FG is small.

Moreover, for example, in case that the word line WL is formed from polysilicon only, there is sometimes more need to consider the likes of lowering of capacitive coupling ratio due to insufficient depletion of the word line WL, increase in resistance due to a thin wire effect, degree of difficulty of controlling silicide amount, and so on. In this regard, in the present embodiment, the word line WL includes a material configured from a metal as the conductive layer 208, hence the word line WL can be suitably miniaturized. Moreover, in the present embodiment, the select gate lines SGD and SGS are configured from polysilicon and do not include a metal, hence can be comparatively easily manufactured.

[Method of Manufacturing]

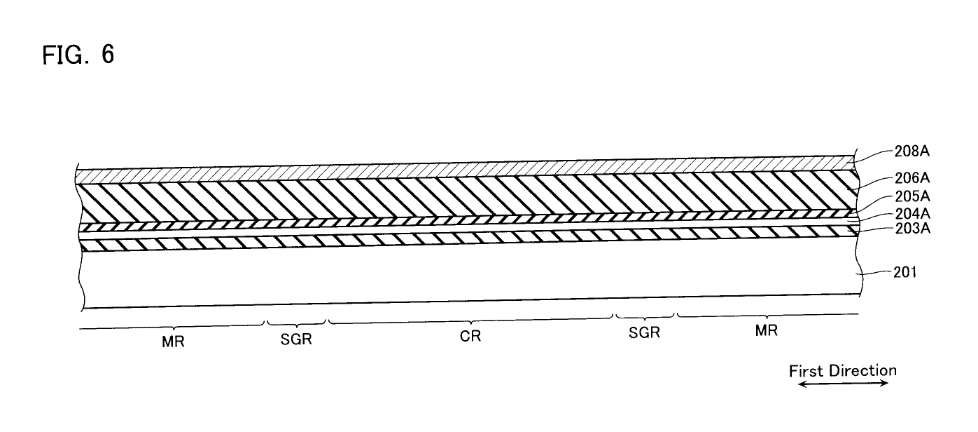

Next, a method of manufacturing the semiconductor memory device according to the present embodiment will be described with reference to FIGS. 6 to 15. FIGS. 6 to 15 are cross-sectional views showing a manufacturing process of the same nonvolatile semiconductor memory device.

As shown in FIG. 6, the following are stacked sequentially on the semiconductor layer 201, namely: an insulating layer 203A which will be the first insulating layer 203; a charge accumulation layer 204A which will be the first charge accumulation layer 204; and a charge accumulation layer 205A which will be the second charge accumulation layer 205. Next, the semiconductor layer 201, the insulating layer 203A, the charge accumulation layer 204A, and the charge accumulation layer 205A are divided in the second direction (refer to FIGS. 4 and 5), and a trench formed by this division is embedded with an insulating layer not illustrated. Next, the following are stacked sequentially on the charge accumulation layer 205A and the insulating layer not illustrated, namely: an insulating layer 206A which will be the second insulating layer 206; and a conductive layer 208A which will be the conductive layer 208.

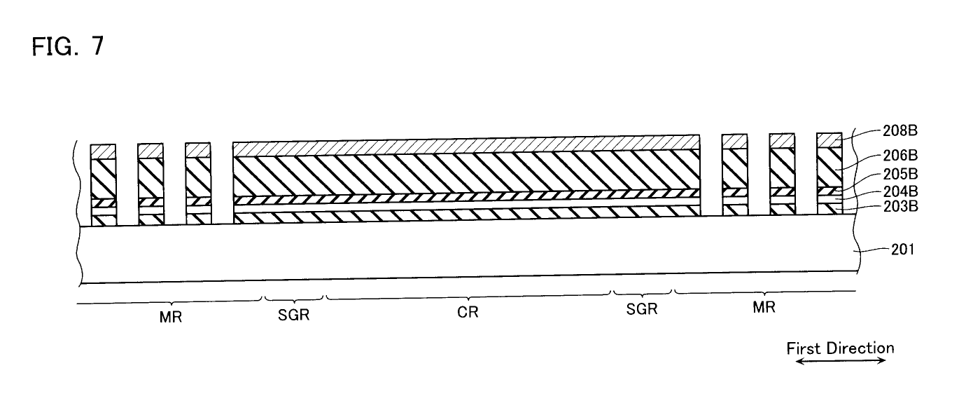

Next, as shown in FIG. 7, a portion provided in the memory region MR, of the insulating layer 203A, the charge accumulation layer 204A, the charge accumulation layer 205A, the insulating layer 206A, and the conductive layer 208A, is divided in the first direction to form an insulating layer 203B, a charge accumulation layer 204B, a charge accumulation layer 205B, an insulating layer 206B, and a conductive layer 208B. Moreover, this process causes a plurality of the memory cells MC to be formed in the memory region MR.

Division of the insulating layer 203A, the charge accumulation layer 204A, the charge accumulation layer 205A, the insulating layer 206A, and the conductive layer 208A may be performed by depositing a resist on the conductive layer 208A and performing the likes of lithography and etching. Moreover, the division may be performed by forming a sacrifice layer on the conductive layer 208A, dividing the sacrifice layer in the first direction by the likes of lithography and etching, further forming a sacrifice layer on a sidewall of the divided sacrifice layer, and performing etching using this sacrifice layer formed on the sidewall as a mask. Furthermore, such a process may be repeatedly performed.

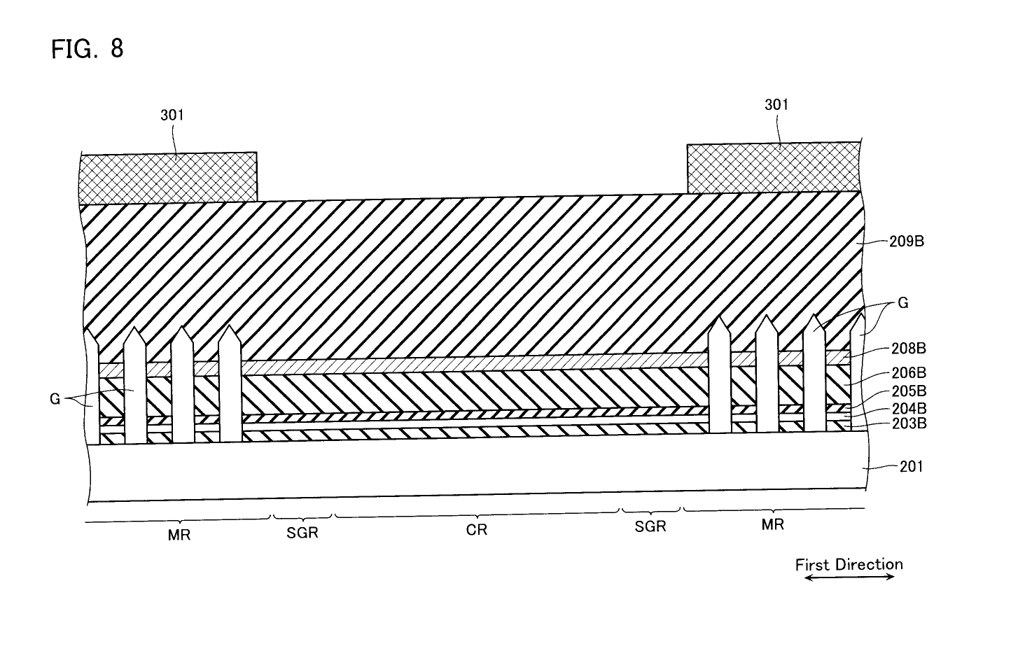

Next, as shown in FIG. 8, an insulating layer 209B which will be the insulating layer 209 is formed on an upper portion of the conductive layer 208B. The insulating layer 209B is formed by a material having poor embedding properties such as plasma silane (P-SiH₄), for example. As a result, a gap G is formed between the plurality of memory cells MC adjacent in the first direction.

Next, as shown in FIG. 8, a resist 301 is formed on an upper surface of the insulating layer 209B. In the present embodiment, the resist 301 covers the memory region MR, but does not cover the select gate region SGR and the contact region CR.

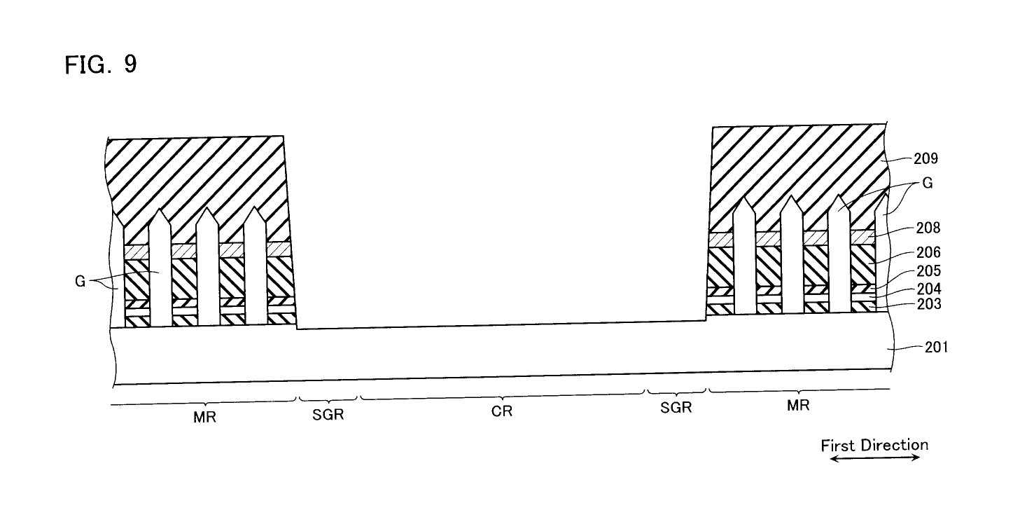

Next, as shown in FIG. 9, the insulating layer 203B, the charge accumulation layer 204B, the charge accumulation layer 205B, the insulating layer 206B, the conductive layer 208B, and the insulating layer 209B positioned in the select gate region SGR and the contact region CR are removed using the resist 301 as a mask, to form the first insulating layer 203, the first charge accumulation layer 204, the second charge accumulation layer 205, the second insulating layer 206, the conductive layer 208, and the insulating layer 209. As shown in FIG. 9, in this process, a side surface in the first direction of the first insulating layer 203, the first charge accumulation layer 204, the second charge accumulation layer 205, the second insulating layer 206, the conductive layer 208, and the insulating layer 209, is exposed. In addition, this side surface is inclined so as to be closer to the select gate region SGR the closer it is to the semiconductor layer 201 and so as to be more distant from the select gate region SGR the more distant it is from the semiconductor layer 201. Moreover, in this process, the upper surface of the semiconductor layer 201 in the select gate region SGR and the contact region CR is lower than the upper surface of the semiconductor layer 201 in the memory region MR.

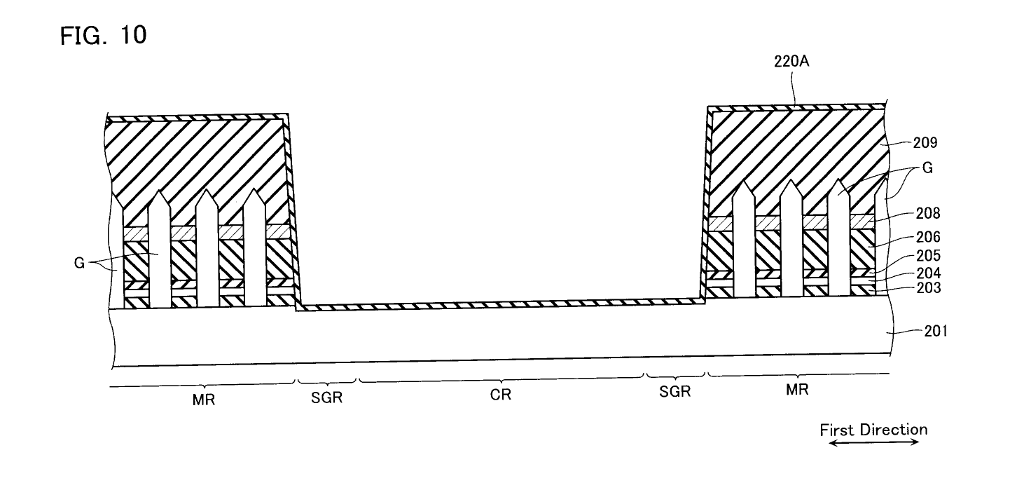

Next, as shown in FIG. 10, an insulating layer 220A which will be the third insulating layer 220, is deposited. The insulating layer 220A contacts the upper surface of the semiconductor layer 201 in the select gate region SGR and contacts the upper surface of the insulating layer 209 in the memory region MR. Moreover, the insulating layer 220A covers the side surface in the first direction of the first insulating layer 203, the first charge accumulation layer 204, the second charge accumulation layer 205, the second insulating layer 206, the conductive layer 208, and the insulating layer 209. Therefore, part of the insulating layer 220A inclines so as to be more distant from the memory region MR the closer it is to the semiconductor layer 201 and so as to be closer to the memory region MR the more distant it is from the semiconductor layer 201, along this side surface.

Note that deposition of the insulating layer 220A is performed by a variety of methods performable at a certain temperature or less. As examples of such methods, the deposition may be performed by a deposition method utilizing plasma, such as PEALD (Plasma Enhanced Atomic Layer Deposition) or LPCVD (Low Pressure Chemical Vapor Deposition), for example. When, for example, PEALD is used to deposit SiO₂ and this is adopted as the insulating layer 220A, it is possible to deposit SiO₂ showing equivalent insulating properties to a method by thermal oxidation.

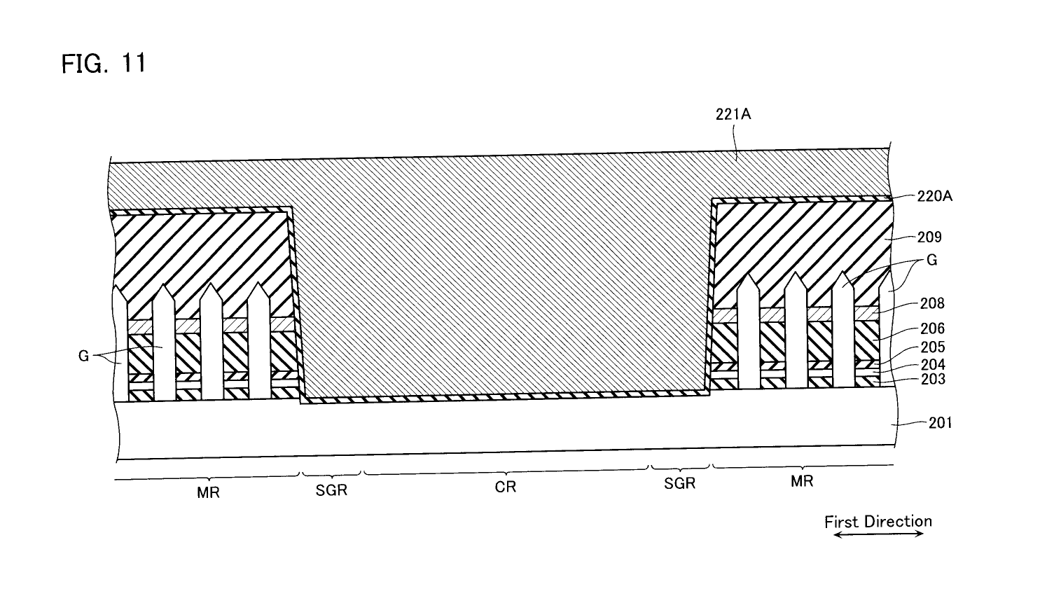

Next, as shown in FIG. 11, a conductive layer 221A which will be the conductive layer 221 configuring the select gate lines SGD and SGS, is formed. Now, the conductive layer 221A is formed on the insulating layer 220A. Therefore, a portion facing the side surface in the first direction of the first insulating layer 203, the first charge accumulation layer 204, the second charge accumulation layer 205, the second insulating layer 206, the conductive layer 208, and the insulating layer 209, via the insulating layer 220A, of the conductive layer 221A inclines so as to be more distant from the memory region MR the closer it is to the semiconductor layer 201 and so as to be closer to the memory region MR the more distant it is from the semiconductor layer 201. Note that the conductive layer 221A may be formed from polysilicon, for example.

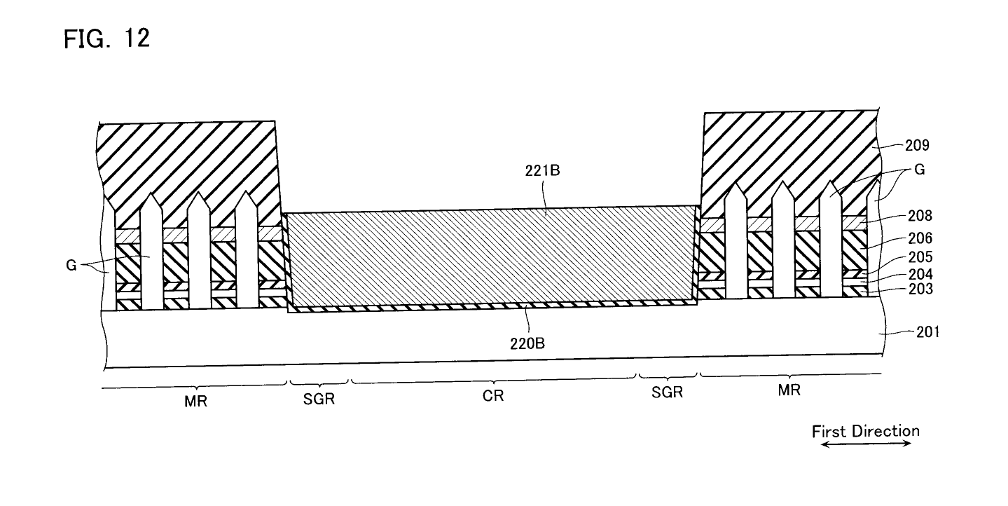

Next, as shown in FIG. 12, parts of the insulating layer 220A and the conductive layer 221A are removed to form an insulating layer 220B and a conductive layer 221B. Upper ends of the insulating layer 220B and the conductive layer 221B are lower than an upper end of the insulating layer 209. As a result, portions forming the select gate transistor S1 (refer to FIG. 2) and portions forming the select gate transistor S2 (refer to FIG. 2) of the insulating layer 220B and the conductive layer 221B, are divided in the first direction.

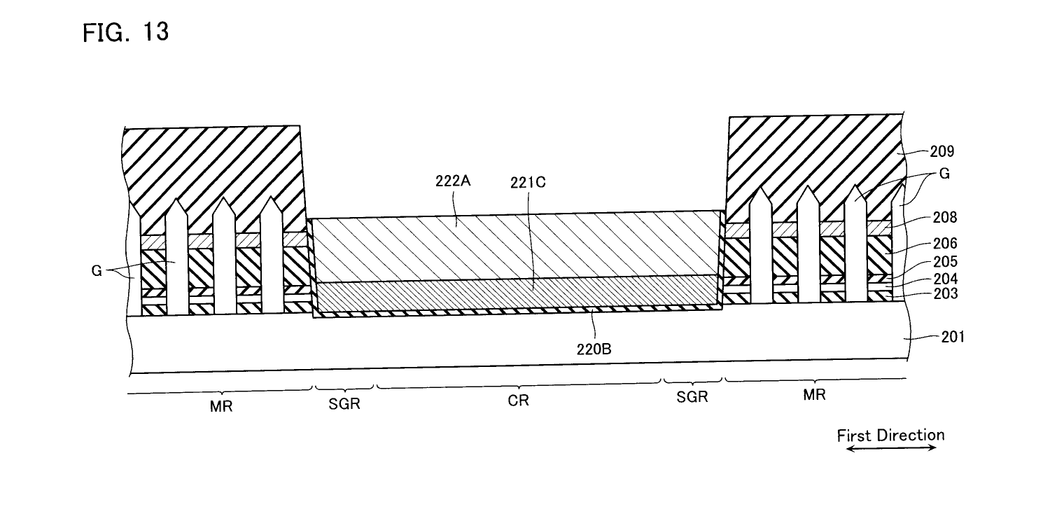

Next, as shown in FIG. 13, part of the conductive layer 221B is silicided to configure an upper portion of the conductive layer 221B as a low-resistance conductive layer 222A and to configure a lower portion of the conductive layer 221B as a conductive layer 221C. Note that it is also possible for the conductive layer 221B to be entirely silicided, for example. Moreover, siliciding of the conductive layer 221B may be omitted.

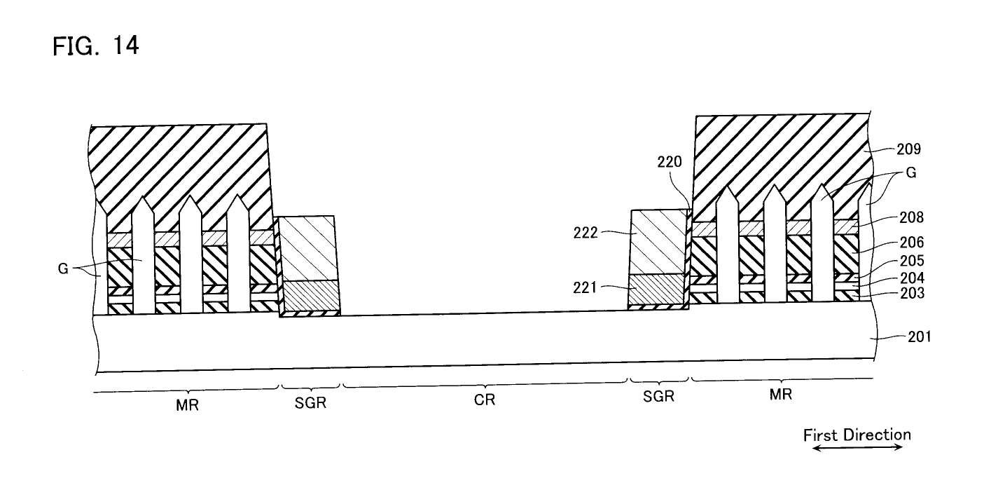

Next, as shown in FIG. 14, portions positioned in the contact region CR, of the insulating layer 220B, the conductive layer 221C, and the conductive layer 222A, are removed to form the third insulating layer 220 and to form the conductive layer 221 and the conductive layer 222 which will be the select gate lines SGD or SGS. These third insulating layer 220, conductive layer 221, and conductive layer 222 are divided in the first direction and become electrically independent from each other. Moreover, in this process, an end surface in the first direction of the conductive layer 221 and the conductive layer 222, is exposed. Furthermore, this end surface inclines so as to be more distant from the memory region MR the closer it is to the semiconductor layer 201 and so as to be closer to the memory region MR the more distant it is from the semiconductor layer 201. Note that when, for example, the conductive layer 221A is formed from polysilicon, removal of the conductive layer 221C and the conductive layer 222A can be performed comparatively easily.

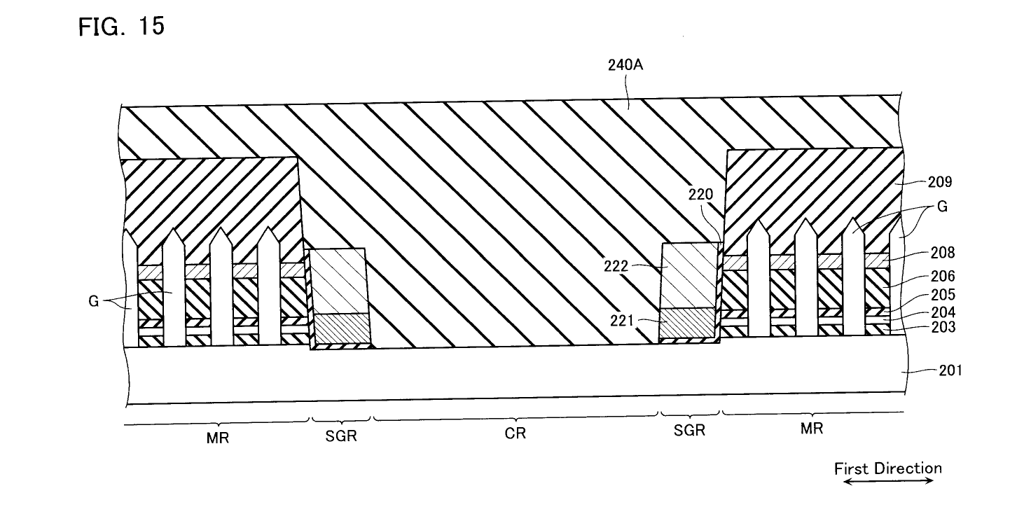

Next, as shown in FIG. 15, an insulating layer 240A which will be the insulating layer 240, is formed. The insulating layer 240A contacts the end surface in the first direction of the conductive layer 221 and the conductive layer 222, and an upper surface of the conductive layer 222.

Subsequently, as shown in FIG. 3, a via hole and a trench that extends in the second direction are formed in the insulating layer 240A, and the upper surface of the semiconductor layer 201 is exposed. Next, a conductive layer which will be the bit line contact CB or the source line contact LI (third conductive layer) is embedded herein. Next, the bit line BL and the source line CELSRC are formed on the insulating layer 240A and the control circuit, and so on, are formed, whereby the semiconductor memory device according to the present embodiment can be manufactured.

Now, as described with reference to FIG. 2, the semiconductor memory device according to the present embodiment includes the select gate transistors S1 and S2 connected to both ends of the NAND string. Now, it is also conceivable that the select gate transistors S1 and S2 are formed utilizing the layers that form the charge accumulation layer FG and the word line WL of the memory cell MC. However, when the select gate transistors S1 and S2 include the charge accumulation layer FG, sometimes, a threshold value of the select gate transistors S1 and S2 ends up fluctuating based on an amount of charge accumulated in this charge accumulation layer FG, and the NAND string to be accessed cannot be suitably selected. Therefore, it is conceivable that when the layers forming the charge accumulation layer FG and the word line WL of the memory cell MC are utilized to form the select gate transistors S1 and S2, part of the inter-gate insulating layer is removed, for example, and the layers forming the charge accumulation layer FG and the word line WL are electrically connected.

However, when, for example, a film thickness of the layers forming the charge accumulation layer FG is small, sometimes, the charge accumulation layer FG also gets removed and, furthermore, part of the tunnel insulating layer gets removed, along with the inter-gate insulating layer. In this case, the layer forming the word line WL and the semiconductor layer sometimes get short-circuited. Note that such a phenomenon begins to occur comparatively frequently when, for example, the film thickness of the charge accumulation layer FG is about 20 nm or less.

In this regard, in the present embodiment, as shown in FIGS. 6 to 15, each of the layers forming the memory cell MC and the layers configuring the select gate lines SGD or SGS are formed in different processes. Therefore, a process for removing part of the inter-gate insulating layer becomes unnecessary, and the above-mentioned kind of phenomenon ceases to occur.

Moreover, in the present embodiment, since each of the layers forming the memory cell MC and the layers configuring the select gate lines SGD or SGS are formed in different processes, it becomes possible to use a different material to that of the word line WL, as a material of the select gate lines SGD and SGS. For example, it is possible to use a material configured from a metal in the word line WL and thereby achieve miniaturization of the word line WL while suppressing resistivity of the word line WL. Moreover, it is possible to configure the select gate lines SGD and SGS from polysilicon and thereby perform processing of the select gate lines comparatively easily.

### Second Embodiment

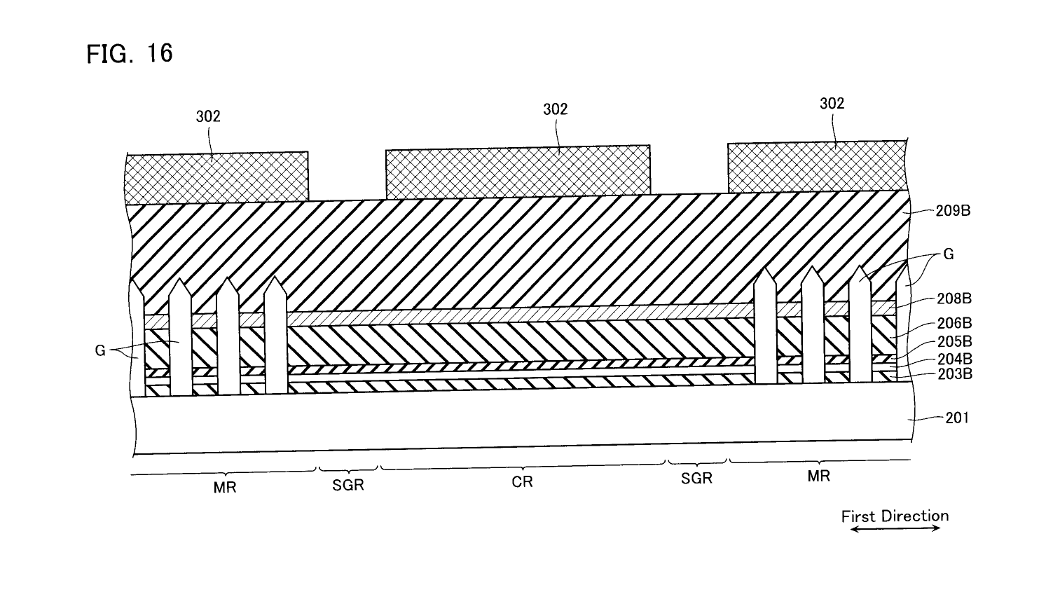

Next, a method of manufacturing a nonvolatile semiconductor memory device according to a second embodiment will be described with reference to FIGS. 16 to 21. FIGS. 16 to 21 are cross-sectional views showing manufacturing processes of the nonvolatile semiconductor memory device according to the second embodiment. In the description below, portions similar to those of the first embodiment are assigned with reference symbols similar to those assigned in the first embodiment, and descriptions of said portions will be omitted.

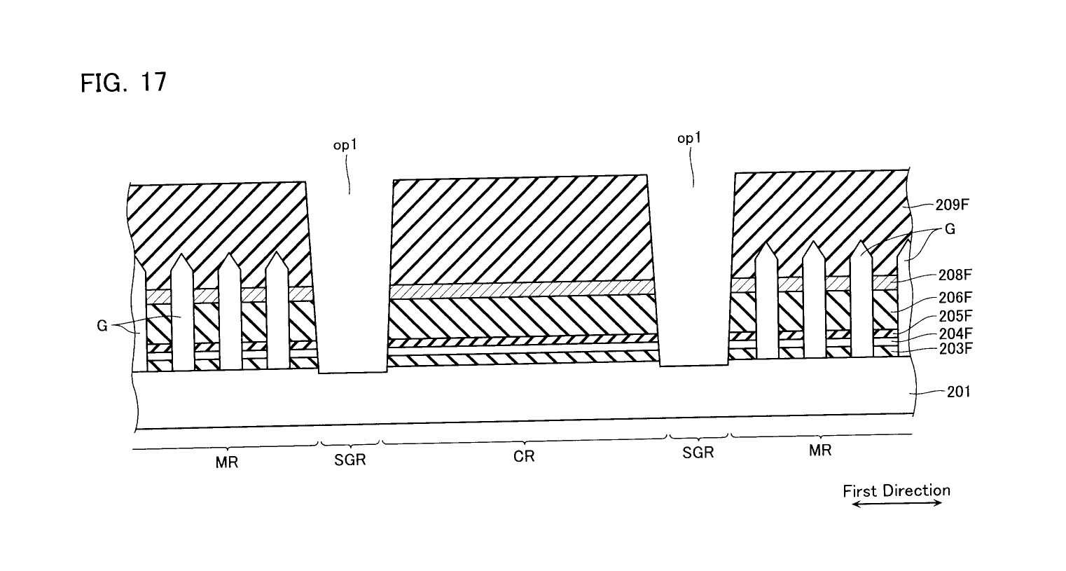

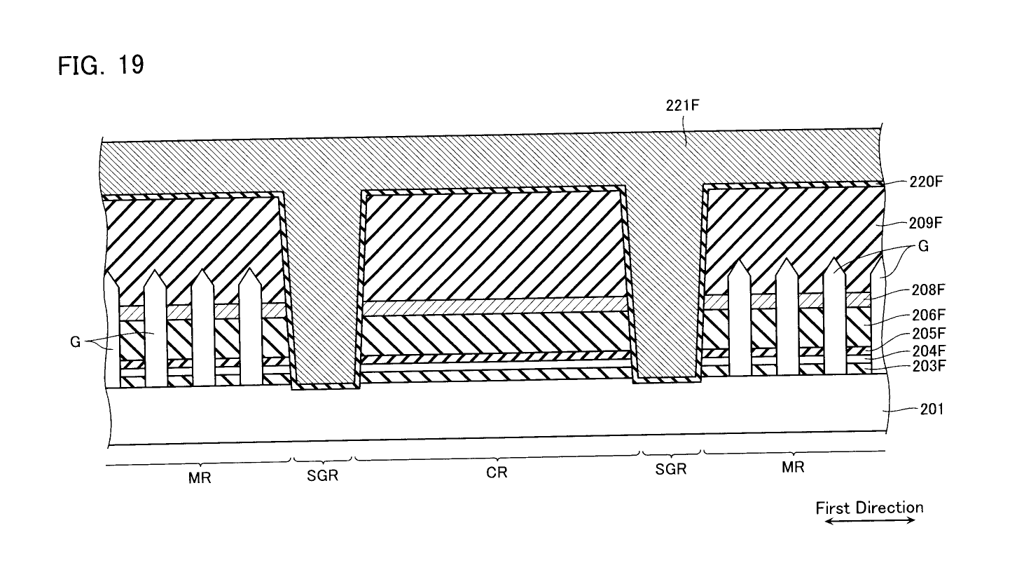

In the method of manufacturing according to the present embodiment, a semiconductor memory device of the kind described with reference to FIGS. 3 to 5 is manufactured, similarly to in the method of manufacturing according to the first embodiment. Moreover, the method of manufacturing according to the present embodiment is basically similar to the method of manufacturing according to the first embodiment. However, in the present embodiment, as shown in FIGS. 16 and 17, only a portion positioned in the select gate region SGR of each of the layers forming the memory cell MC is removed, and as shown in FIG. 19, a conductive layer 221F is formed herein. Therefore, in the present embodiment, an amount of the conductive layer 221F used can be reduced more compared to in the case shown in FIG. 11.

The method of manufacturing a semiconductor memory device according to the present embodiment is performed similarly to that of the first embodiment up to the process described with reference to FIG. 7. Next, as shown in FIG. 16, the insulating layer 209B which will be the insulating layer 209 is formed on the upper portion of the conductive layer 208B, and a resist 302 is formed on the upper surface of the insulating layer 209B, by a process similar to the process described with reference to FIG. 8. In the present embodiment, the resist 302 covers the memory region MR and the contact region CR, but does not cover the select gate region SGR.

Next, as shown in FIG. 17, the insulating layer 203B, the charge accumulation layer 204B, the charge accumulation layer 205B, the insulating layer 206B, the conductive layer 208B, and the insulating layer 209B positioned in the select gate region SGR are removed using the resist 302 as a mask, to form an insulating layer 203F, a charge accumulation layer 204F, a charge accumulation layer 205F, an insulating layer 206F, a conductive layer 208F, and an insulating layer 209F. As shown in FIG. 17, these layers include an opening op1 that exposes the upper surface of the semiconductor layer 201 in the select gate region SGR. Note that the opening op1 is a trench extending along the second direction (refer to FIGS. 4 and 5). In other respects, this process is performed similarly to the process described with reference to FIG. 9.

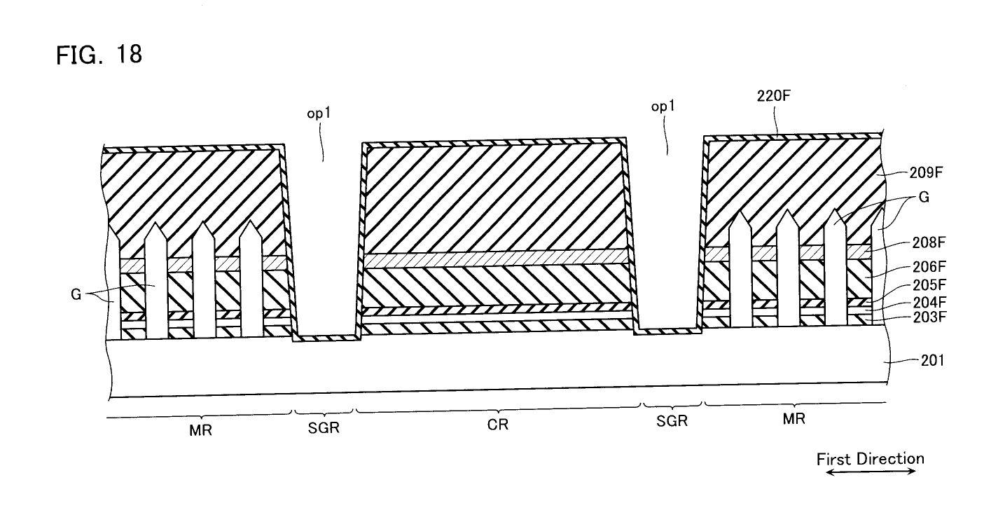

Next, as shown in FIG. 18, an insulating layer 220F which will be the third insulating layer 220, is deposited. This process is performed similarly to the process described with reference to FIG. 10.

Next, as shown in FIG. 19, a conductive layer 221F which will be the conductive layer 221 configuring the select gate lines SGD and SGS, is formed. Now, the conductive layer 221F is deposited also on a sidewall of the opening op1. Therefore, the opening op1 can be embedded by a smaller amount of material compared to in the process described with reference to FIG. 11, for example. Note that in other respects, this process is performed similarly to the process described with reference to FIG. 11.

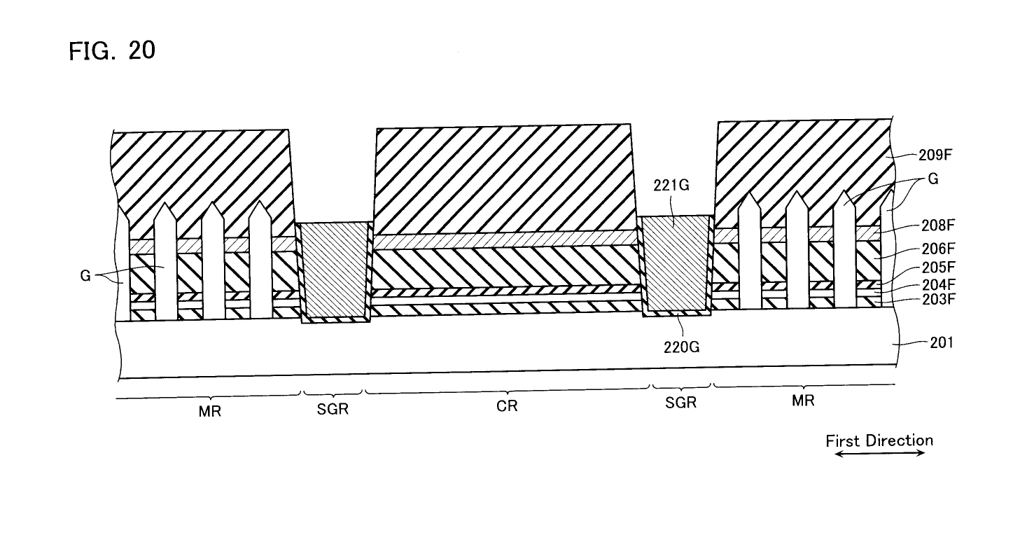

Next, as shown in FIG. 20, parts of the insulating layer 220F and the conductive layer 221F are removed to form an insulating layer 220G and a conductive layer 221G. This process is performed similarly to the process described with reference to FIG. 12.

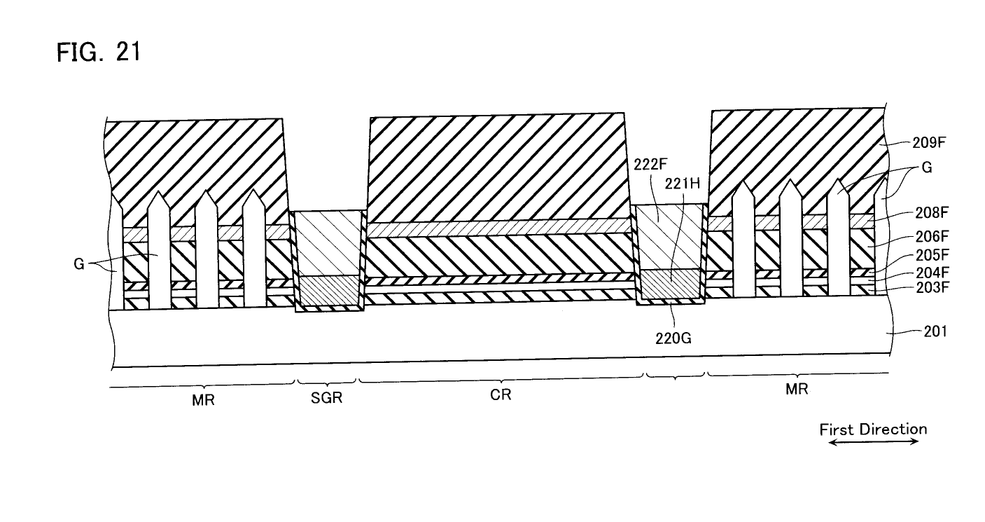

Next, as shown in FIG. 21, part of the conductive layer 221G is silicided to configure an upper portion of the conductive layer 221G as a low-resistance conductive layer 222F and to configure a lower portion of the conductive layer 221G as a conductive layer 221H. This process is performed similarly to the process described with reference to FIG. 13.

Next, as shown in FIG. 14, portions close to the contact region CR, of the insulating layer 220G, the conductive layer 221H, and the conductive layer 222F, are removed to form the third insulating layer 220 and to form the conductive layer 221 and the conductive layer 222 which will be the select gate lines SGD or SGS. In addition, the insulating layer 203F, the charge accumulation layer 204F, the charge accumulation layer 205F, the insulating layer 206F, the conductive layer 208F, and the insulating layer 209F positioned in the contact region CR are removed to form the first insulating layer 203, the first charge accumulation layer 204, the second charge accumulation layer 205, the second insulating layer 206, the conductive layer 208, and the insulating layer 209.

### Third Embodiment

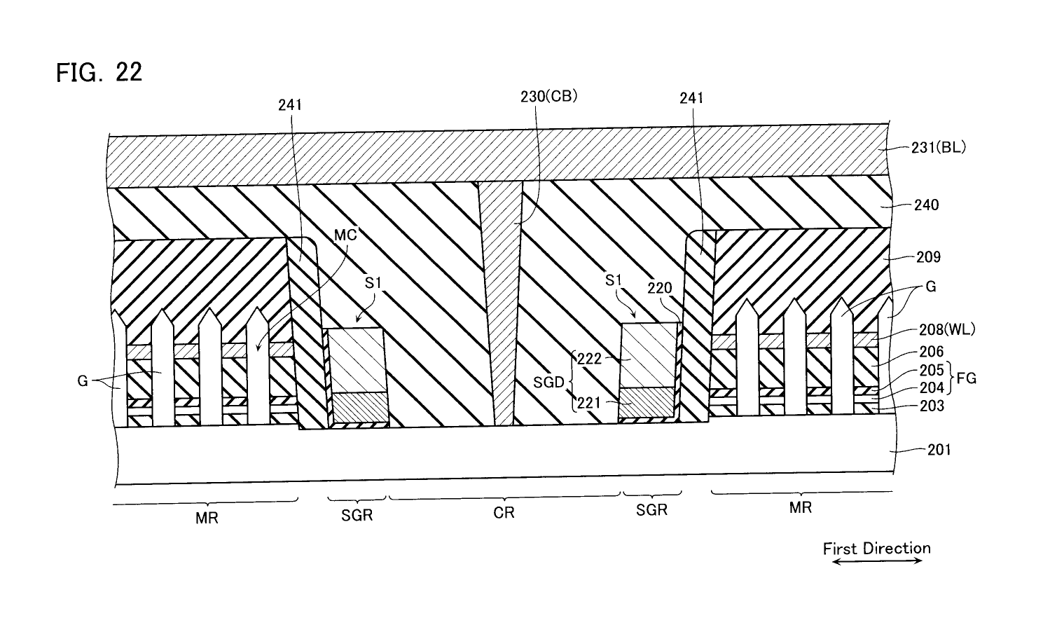

Next, a nonvolatile semiconductor memory device according to a third embodiment will be described with reference to FIG. 22. FIG. 22 is a schematic cross-sectional view showing a configuration of part of the nonvolatile semiconductor memory device according to the third embodiment. In the description below, portions similar to those of the first embodiment are assigned with reference symbols similar to those assigned in the first embodiment, and descriptions of said portions will be omitted.

As shown in FIG. 22, the semiconductor memory device according to the present embodiment is basically similar to the semiconductor memory device according to the first embodiment. However, in the present embodiment, a spacer (fourth insulating layer) 241 is formed between the memory cell MC positioned at an end in the first direction of the memory region MR and the select gate transistor S1 or S2. Therefore, in the present embodiment, it is possible to suitably adjust a distance between the memory cell MC positioned at the end in the first direction of the memory region MR and the select gate transistor S1 or S2.

Note that in the present embodiment, the spacer 241 contacts the semiconductor layer 201 at a lower surface of the spacer 241. In addition, the spacer 241 contacts the first insulating layer 203, the first charge accumulation layer 204, the second charge accumulation layer 205, the second insulating layer 206, the conductive layer 208, and the insulating layer 209 at one of side surfaces of the spacer 241. Moreover, the spacer 241 contacts the third insulating layer 220 and the insulating layer 240 at the other of the side surfaces of the spacer 241. Furthermore, both side surfaces in the first direction of the spacer insulating layer are inclined so as to be more distant from the memory region MR the closer they are to the semiconductor layer 201 and so as to be closer to the memory region MR the more distant they are from the semiconductor layer 201.

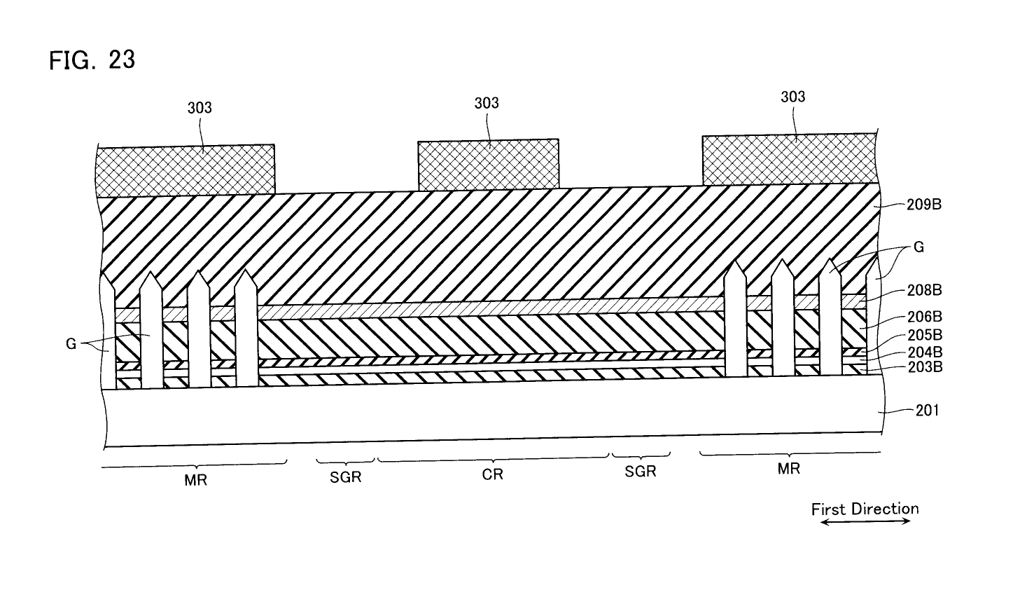

Next, a method of manufacturing the nonvolatile semiconductor memory device according to the present embodiment will be described with reference to FIGS. 23 to 31. FIGS. 23 to 31 are cross-sectional views showing manufacturing processes of the nonvolatile semiconductor memory device according to the third embodiment.

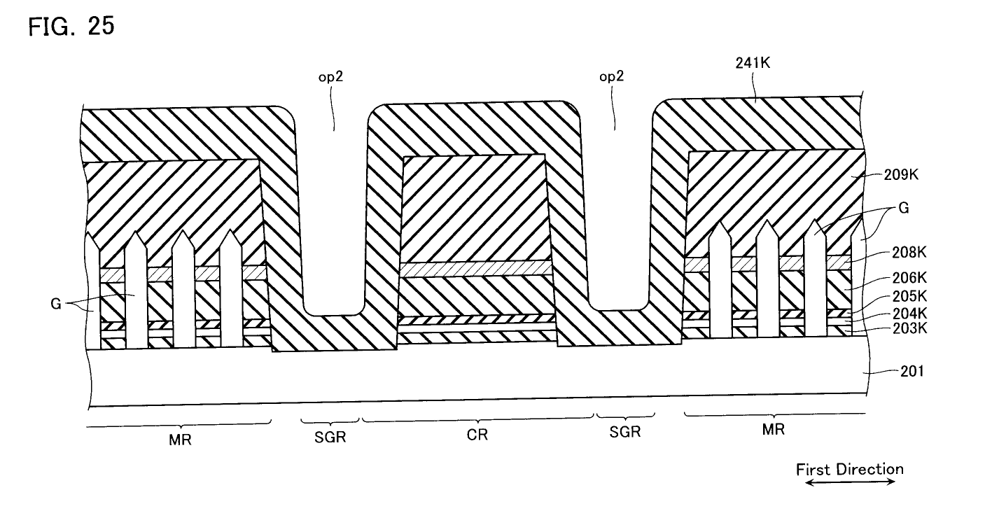

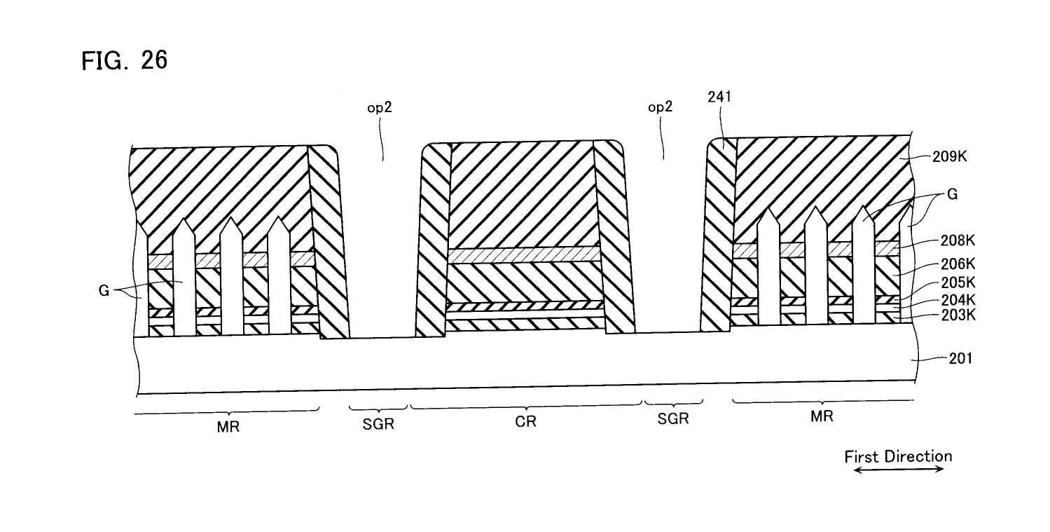

The method of manufacturing according to the present embodiment is basically similar to the methods of manufacturing according to the first and second embodiments. However, in the present embodiment, the spacer 241 is formed, as shown in FIGS. 25 and 26.

The method of manufacturing a semiconductor memory device according to the present embodiment is performed similarly to that of the first embodiment up to the process described with reference to FIG. 7. Next, as shown in FIG. 23, the insulating layer 209B which will be the insulating layer 209 is formed on the upper portion of the conductive layer 208B, and a resist 303 is formed on the upper surface of the insulating layer 209B, by a process similar to the process described with reference to FIG. 8. In the present embodiment, the resist 303 covers the memory region MR and the contact region CR, but does not cover the select gate region SGR.

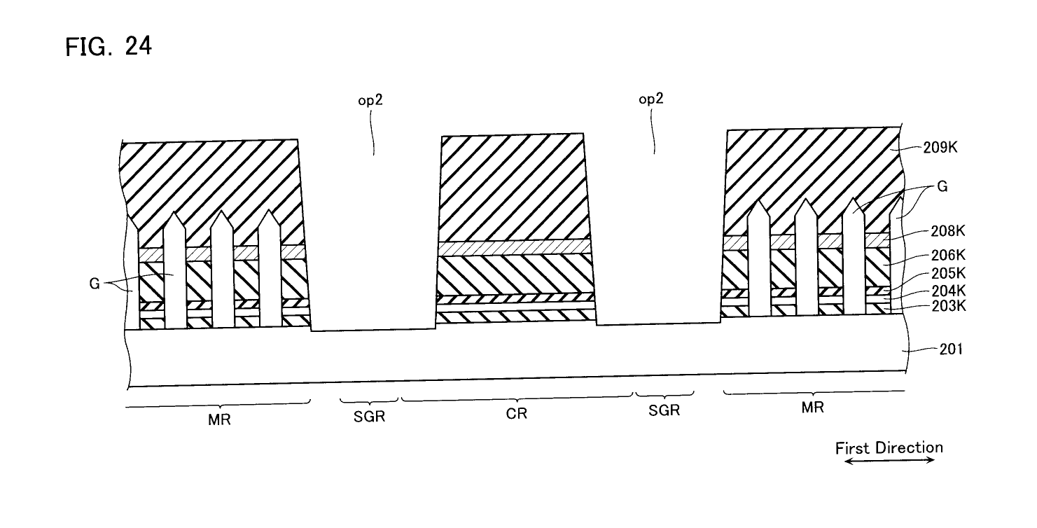

Next, as shown in FIG. 24, the insulating layer 203B, the charge accumulation layer 204B, the charge accumulation layer 205B, the insulating layer 206B, the conductive layer 208B, and the insulating layer 209B positioned in the select gate region SGR are removed using the resist 303 as a mask, to form an insulating layer 203K, a charge accumulation layer 204K, a charge accumulation layer 205K, an insulating layer 206K, a conductive layer 208K, and an insulating layer 209K. As shown in FIG. 24, these layers include an opening op2 that exposes the upper surface of the semiconductor layer 201 in the select gate region SGR. Note that the opening op2 is a trench extending along the second direction (refer to FIGS. 4 and 5). In other respects, this process is performed similarly to the process described with reference to FIG. 9.

Next, as shown in FIG. 25, an insulating layer 241K which will be the spacer 241, is formed. The insulating layer 241K covers a side surface in the first direction of the insulating layer 203K, the charge accumulation layer 204K, the charge accumulation layer 205K, the insulating layer 206K, the conductive layer 208K, and the insulating layer 209K. Therefore, part of the insulating layer 241K inclines so as to be more distant from the memory region MR the closer it is to the semiconductor layer 201 and so as to be closer to the memory region MR the more distant it is from the semiconductor layer 201, along this side surface. Note that the insulating layer 241K covers also an upper surface of the insulating layer 209K and the upper surface of the semiconductor layer 201.

Next, as shown in FIG. 26, the insulating layer 241K is removed leaving a portion thereof that covers the side surface in the first direction of the insulating layer 203K, the charge accumulation layer 204K, the charge accumulation layer 205K, the insulating layer 206K, the conductive layer 208K, and the insulating layer 209K. As a result, the spacer 241 is formed. Moreover, the upper surface of the insulating layer 209K is exposed in the memory region MR, and the semiconductor layer 201 is exposed in the contact region CR.

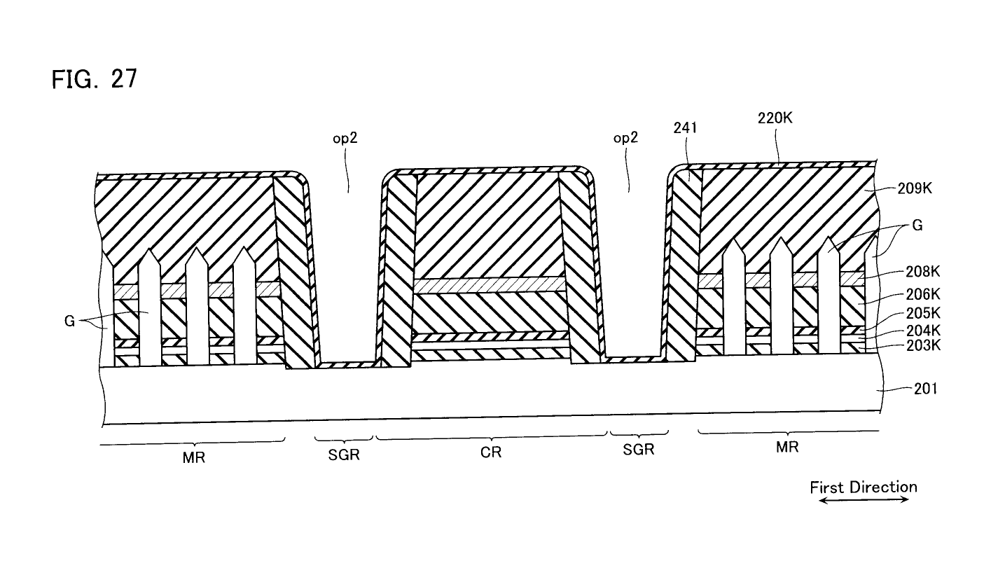

Next, as shown in FIG. 27, an insulating layer 220K which will be the third insulating layer 220, is deposited. The insulating layer 220K covers a side surface in the first direction of the spacer 241. Therefore, part of the insulating layer 220K inclines so as to be more distant from the memory region MR the closer it is to the semiconductor layer 201 and so as to be closer to the memory region MR the more distant it is from the semiconductor layer 201, along this side surface. Note that the insulating layer 220K covers also the upper surface of the insulating layer 209K and the upper surface of the semiconductor layer 201. In other respects, this process is performed similarly to the process described with reference to FIG. 10.

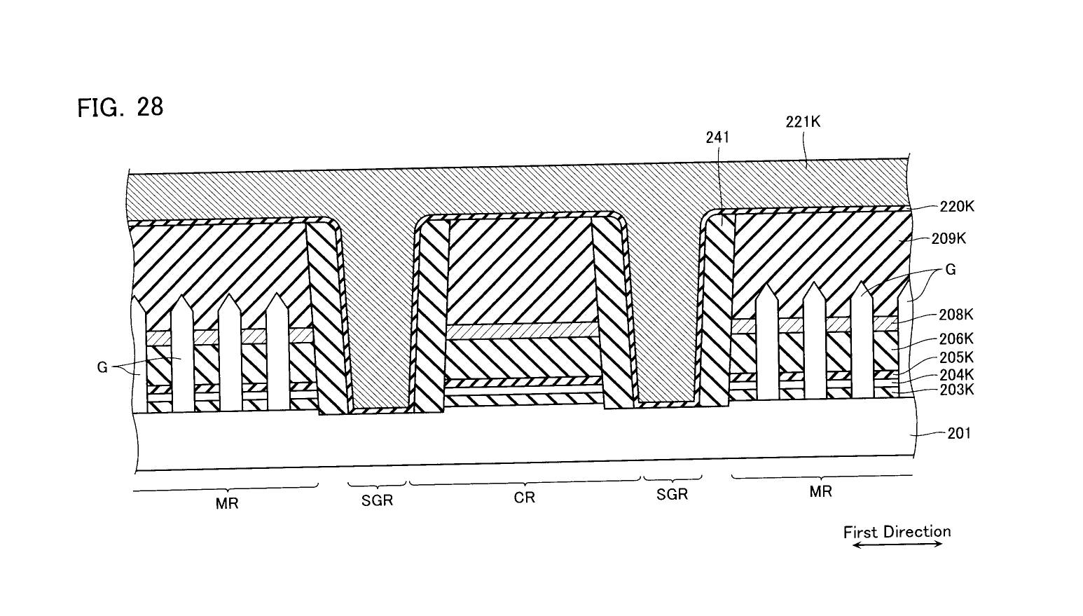

Next, as shown in FIG. 28, a conductive layer 221K which will be the conductive layer 221 configuring the select gate lines SGD or SGS, is formed. This process is performed similarly to the process described with reference to FIG. 19.

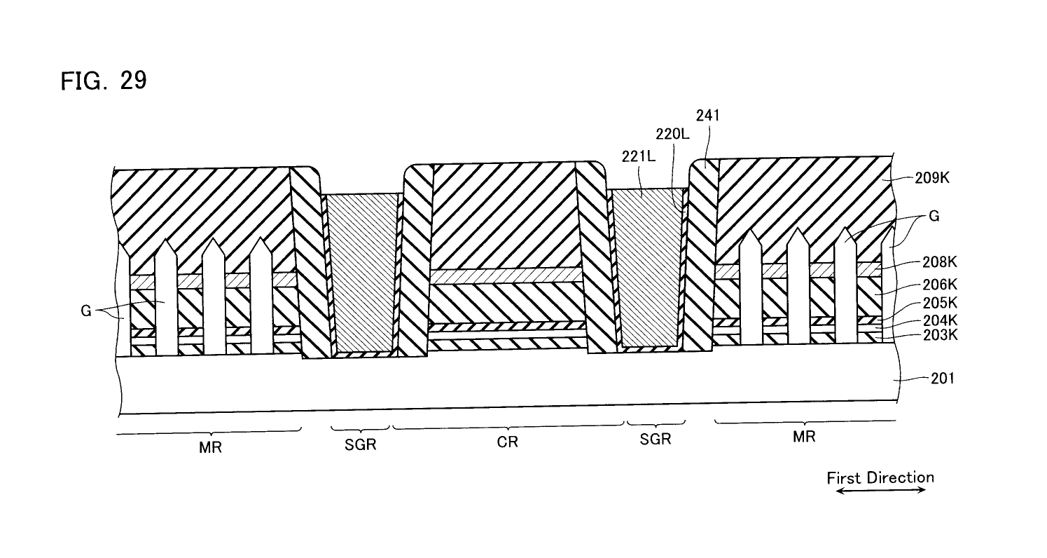

Next, as shown in FIG. 29, parts of the insulating layer 220K and the conductive layer 221K are removed to form an insulating layer 220L and a conductive layer 221L. This process is performed similarly to the process described with reference to FIG. 12.

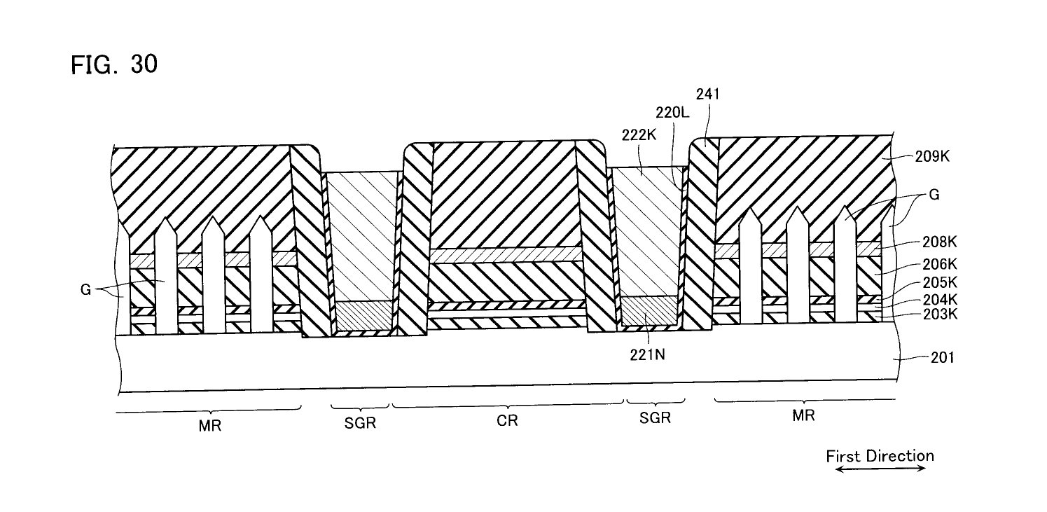

Next, as shown in FIG. 30, part of the conductive layer 221L is silicided to configure an upper portion of the conductive layer 221L as a low-resistance conductive layer 222K and to configure a lower portion of the conductive layer 221L as a conductive layer 221N. This process is performed similarly to the process described with reference to FIG. 13.

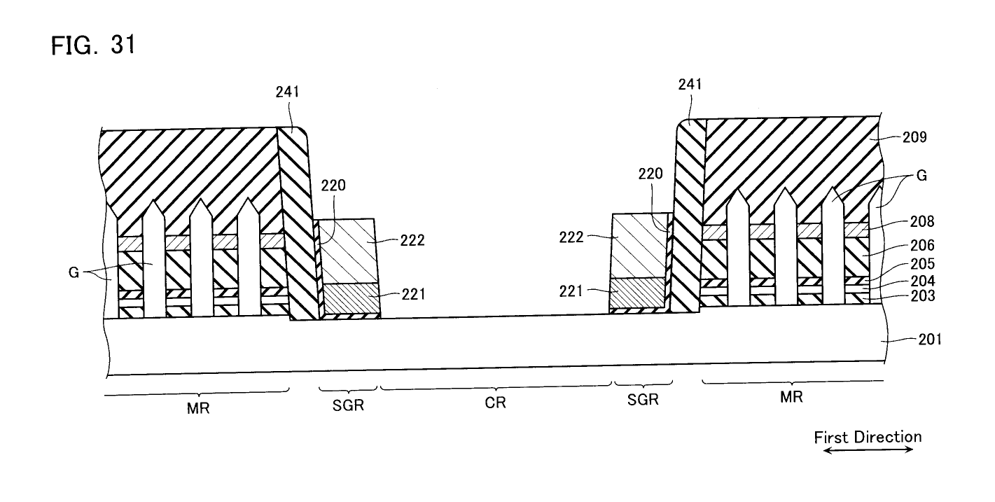

Next, as shown in FIG. 31, each of the layers in the contact region CR and a region adjacent to the contact region CR, is removed. This process is performed similarly to the process described with reference to FIG. 14.

In the present embodiment, the distance between the memory cell MC positioned at the end of the memory region MR and the select gate transistor S1 or S2 can be suitably adjusted by the spacer 241.

Moreover, it is also conceivable that, for example, when the conductive layers forming the charge accumulation layer FG and the word line WL of the memory cell MC are utilized to form the select gate transistor, the distance between the memory cell MC and the select gate transistor is adjusted during patterning (division in the first direction) of the memory cell MC.

However, sometimes, in such a case, the distance between the memory cell MC and the select gate transistor ends up being larger than a distance between fellow memory cells MC, and the semiconductor layer gets greatly shaved (gouging ends up occurring) between the memory cell MC and the select gate transistor.

In this regard, in the present embodiment, the spacer is formed after the memory cell MC has been formed, whereby the distance between the memory cell MC and the select gate transistor is adjusted and then the select gate transistor is formed. Therefore, it is possible to prevent occurrence of the above-mentioned gouging and to suitably adjust the distance between the memory cell MC and the select gate transistor.

### Other Embodiments

As shown in FIGS. 23 and 24, in the third embodiment, the opening op2 is formed using the resist 303 that covers the memory region MR and the contact region CR but does not cover the select gate region SGR, similarly to in the second embodiment. However, it is also possible to use in the third embodiment a resist that covers the memory region MR but does not cover the select gate region SGR and the contact region CR, similarly to in the first embodiment.

In addition, as shown in FIG. 22, in the third embodiment, the spacer 241 was provided between the third insulating layer 220 and the memory cell MC. However, the spacer 241 may be provided between the select gate line SGS or SGD and the third insulating layer 220, for example.

Moreover, in the process for manufacturing the select gate transistors S1 and S2, it is possible to manufacture a transistor also in a peripheral circuit and use this transistor to configure the control circuit described with reference to FIG. 1. Note that the transistor formed in this way may be handled as, for example, a comparatively low-voltage handling transistor among a plurality of transistors configuring the control circuit.

[Others]

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of manufacturing a semiconductor memory device, the semiconductor memory device comprising:
a NAND string provided in a first region on a semiconductor layer extending in a first direction, the NAND string including a plurality of memory cells connected in series; and
a select gate transistor connected to an end of the NAND string in a second region on the semiconductor layer, the second region being adjacent to the first region from the first direction,
the method comprising:
stacking on the semiconductor layer a first insulating layer which will be a gate insulating layer of the memory cell;
stacking on the first insulating layer a charge accumulation layer formation layer which will be a charge accumulation layer of the memory cell;
stacking on the charge accumulation layer formation layer a second insulating layer which will be an inter-gate insulating layer of the memory cell;
stacking on the second insulating layer a first conductive layer which will be a control gate electrode of the memory cell;
in the second region, removing the first insulating layer, the charge accumulation layer formation layer, the second insulating layer, and the first conductive layer to expose the semiconductor layer;
stacking in the second region a third insulating layer which will be a gate insulating layer of the select gate transistor; and
forming on the third insulating layer a second conductive layer which will be a gate electrode of the select gate transistor.

2. The method of manufacturing a semiconductor memory device according to claim 1, further comprising:
stacking the third insulating layer so as to cover a sidewall of the first insulating layer, the charge accumulation layer formation layer, the second insulating layer, and the first conductive layer stacked in the first region, from the first direction.

3. The method of manufacturing a semiconductor memory device according to claim 1, wherein
the semiconductor memory device further comprises a contact that contacts the semiconductor layer in a third region on the semiconductor layer, the third region being adjacent to the first region via the second region, and
the method further comprises:
when removing the first insulating layer, the charge accumulation layer formation layer, the second insulating layer, and the first conductive layer in the second region, removing the first insulating layer, the charge accumulation layer formation layer, the second insulating layer, and the first conductive layer also in the third region;
stacking the third insulating layer and the second conductive layer also in the third region; and
removing the third insulating layer and the second conductive layer stacked in the third region.

4. The method of manufacturing a semiconductor memory device according to claim 1, wherein
the semiconductor memory device further comprises a contact that contacts the semiconductor layer in a third region on the semiconductor layer, the third region being adjacent to the first region via the second region, and
the method further comprises:
when removing the first insulating layer, the charge accumulation layer formation layer, the second insulating layer, and the first conductive layer in the second region, forming an opening between the first insulating layer, the charge accumulation layer formation layer, the second insulating layer, and the first conductive layer stacked in the first region and the third region;
stacking the third insulating layer and the second conductive layer inside the opening; and
removing the first insulating layer, the charge accumulation layer formation layer, the second insulating layer, and the first conductive layer stacked in the third region.

5. The method of manufacturing a semiconductor memory device according to claim 1, further comprising:
in the second region, after removing the first insulating layer, the charge accumulation layer formation layer, the second insulating layer, and the first conductive layer and before forming the second conductive layer, forming a fourth insulating layer that covers a sidewall of the charge accumulation layer formation layer and the first conductive layer, from the first direction.

6. The method of manufacturing a semiconductor memory device according to claim 1, wherein
a film thickness of the charge accumulation layer formation layer is 20 nm or less.

7. The method of manufacturing a semiconductor memory device according to claim 1, wherein
the first conductive layer includes a layer configured from a metal, and
the second conductive layer does not include a layer configured from a metal.

8. The method of manufacturing a semiconductor memory device according to claim 1, further comprising:
forming the second conductive layer such that both end surfaces in the first direction of the second conductive layer incline so as to be more distant from the first region the closer they are to the semiconductor layer and so as to be closer to the first region the more distant they are from the semiconductor layer.

9. A semiconductor memory device, comprising:
a NAND string including a plurality of memory cells connected in series; and
a select gate transistor connected to an end of the NAND string,
the memory cell comprising:
a semiconductor layer extending in a first direction;
a charge accumulation layer provided in a first region on the semiconductor layer, the charge accumulation layer facing the semiconductor layer via a gate insulating layer; and
a control gate electrode facing the charge accumulation layer via an inter-gate insulating layer, and
the select gate transistor comprising:
a gate insulating layer provided in a second region on the semiconductor layer and contacting the semiconductor layer, the second region being adjacent to the first region from the first direction; and
a gate electrode formed on the gate insulating layer, both end surfaces in the first direction of the gate electrode inclining so as to be more distant from the first region the closer they are to the semiconductor layer and so as to be closer to the first region the more distant they are from the semiconductor layer.

10. The semiconductor memory device according to claim 9, wherein
the gate insulating layer of the select gate transistor covers a sidewall of the charge accumulation layer and the control gate electrode positioned at an end of the first region, from the first direction.

11. The semiconductor memory device according to claim 9, further comprising:
a fourth insulating layer positioned between the control gate electrode positioned at an end of the first region and the gate electrode.

12. The semiconductor memory device according to claim 9, wherein
a film thickness of the charge accumulation layer is 20 nm or less.

13. The semiconductor memory device according to claim 9, wherein
the control gate electrode includes a layer configured from a metal, and
the gate electrode does not include a layer configured from a metal.

14. A method of manufacturing a semiconductor memory device, comprising:
stacking a first insulating layer on a semiconductor layer, the semiconductor layer being provided with a first region, a second region, and a third region that are adjacent in a first direction;
stacking a charge accumulation layer formation layer on the first insulating layer;
stacking a second insulating layer on the charge accumulation layer formation layer;
stacking a first conductive layer on the second insulating layer;
in the second region, removing the first insulating layer, the charge accumulation layer formation layer, the second insulating layer, and the first conductive layer to expose the semiconductor layer;
stacking in the second region a third insulating layer that contacts the semiconductor layer;
stacking a second conductive layer on the third insulating layer; and
exposing an upper surface of the semiconductor layer in the third region.

15. The method of manufacturing a semiconductor memory device according to claim 14, further comprising:
after exposing the upper surface of the semiconductor layer in the third region, forming in the third region a third conductive layer that contacts the semiconductor layer.

16. The method of manufacturing a semiconductor memory device according to claim 14, further comprising:
stacking the third insulating layer so as to cover a sidewall of the first insulating layer, the charge accumulation layer formation layer, the second insulating layer, and the first conductive layer stacked in the first region, from the first direction.

17. The method of manufacturing a semiconductor memory device according to claim 14, further comprising:
when removing the first insulating layer, the charge accumulation layer formation layer, the second insulating layer, and the first conductive layer in the second region, removing the first insulating layer, the charge accumulation layer formation layer, the second insulating layer, and the first conductive layer also in the third region;
stacking the third insulating layer and the second conductive layer also in the third region; and
when exposing the upper surface of the semiconductor layer in the third region, removing the third insulating layer and the second conductive layer stacked in the third region.

18. The method of manufacturing a semiconductor memory device according to claim 14, further comprising:
when removing the first insulating layer, the charge accumulation layer formation layer, the second insulating layer, and the first conductive layer in the second region, forming an opening between the first insulating layer, the charge accumulation layer formation layer, the second insulating layer, and the first conductive layer stacked in the first region and the third region;
stacking the third insulating layer and the second conductive layer inside the opening; and
when exposing the upper surface of the semiconductor layer in the third region, removing part of the third insulating layer and the second conductive layer, and removing the first insulating layer, the charge accumulation layer formation layer, the second insulating layer, and the first conductive layer stacked in the third region.

19. The method of manufacturing a semiconductor memory device according to claim 14, further comprising:
in the second region, after removing the first insulating layer, the charge accumulation layer formation layer, the second insulating layer, and the first conductive layer and before stacking the second conductive layer, forming a fourth insulating layer that covers a sidewall of the charge accumulation layer formation layer and the first conductive layer, from the first direction.

20. The method of manufacturing a semiconductor memory device according to claim 14, wherein
a film thickness of the charge accumulation layer formation layer is 20 nm or less.
